(19) United States
(12) Patent Application Publication
(10) Pub. No.: US 2005/0250267 A1
(43) Pub. Date: Nov. 10, 2005

(54) Method of heat treating thin film transistor using metal induced lateral crystallization

(76) Inventor: Woon Suh Paik, Gyeonggi-do (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 11/119,772

(22) Filed: May 3, 2005

(30) Foreign Application Priority Data
May 4, 2004 (KR) 10-2004-0031433

(51) Int. Cl. H01L 21/84

(52) U.S. Cl. 438/166

(57) ABSTRACT

A method of heat treating a thin film transistor using a metal induced lateral crystallization (MILC) method is provided, which does not deteriorate performance of a poly-silicon thin film transistor and can perform a MILC heat treatment at lower cost, in forming the poly-silicon thin film transistor by the MILC method. The thin film transistor heat treatment method includes the steps of: forming an amorphous silicon film on an insulation substrate; forming an amorphous silicon thin film transistor using the amorphous silicon film; primarily heat treating the amorphous silicon thin film transistor at a low temperature for a long time under the atmosphere of vacuum, by a MILC method, to thus crystallize the amorphous silicon film in the thin film transistor to be transformed into a poly-crystallized film; and secondarily heat treating the poly-silicon thin film transistor under the atmosphere of hydrogen at a low temperature for a short time, and recovering electrical characteristics of the heat-treated poly-silicon thin film transistor under the vacuum atmosphere.

### BACKGROUND OF THE INVENTION

1. Field of the Invention

The present invention relates to a method of heat treating a thin film transistor using a metal induced lateral crystallization (MILC) method which does not deteriorate performance of a poly-silicon thin film transistor and can perform a MILC heat treatment at lower cost, in forming the poly-silicon thin film transistor by the MILC method.

2. Description of the Related Art

A poly-silicon film is used in a semiconductor layer for a thin film transistor. The poly-silicon film is formed by depositing an amorphous silicon film on a substrate and then crystallizing the amorphous silicon film at a predetermined temperature.

As a method of crystallizing an amorphous silicon film, there are a metal induced lateral crystallization (MILC) method, an Eximer laser annealing (ELA) method by laser crystallization, and a solid phase crystallization (SPC) method by high-temperature heat treatment.

In the case of the MILC method, heat treatment equipment such as a tubular furnace can be used. The MILC method has merits having relatively low processing temperature and short processing time. However, in the case that heat treatment of an amorphous silicon film is performed under the vacuum atmosphere, or at the state where an insulation film exists, electrical characteristics of the formed poly-silicon thin film transistor become worse. To prevent this, the amorphous silicon film is heat treated under the atmosphere of hydrogen.

A conventional method of fabricating a thin film transistor using a MILC method will follow.

FIGS. 1A through 1D are cross-sectional views for explaining a conventional poly-silicon thin film transistor fabrication method using a MILC method, respectively.

Referring to FIG. 1A, a buffer layer 10 made of an oxide film is formed on an insulation substrate such as a glass substrate (not shown), and then an amorphous silicon film is formed on the buffer layer 10. Then, the amorphous silicon film is patterned by a photographic etching process to thereby form a semiconductor layer 11, and subsequently, an insulation film and a metal film are deposited on a substrate by a PECVD (Plasma Enhanced Vapor Deposition) method and a sputtering method, respectively, and then patterned by the photographic etching process, to thereby form a gate electrode 13 and a gate insulation film 12.

Then, referring to FIG. 1B, a source region 11S and a drain region 11D are formed through an ion injection process of injecting impurities. Then, as shown in FIG. 1C, an off-set structure is formed using a photosensitive agent 14 such as a photoresist. Then, a nickel (Ni) film 15 is deposited on the entire substrate surface for performing metal induced lateral crystallization (MILC). Then, referring to FIG. 1D, the photosensitive agent 14 is removed by using a lift-off method, and then a MILC heat treatment is performed at a temperature between 400° C. through 600° C. under the atmosphere of hydrogen, to thereby crystallize a channel portion 16.

Such long-time heat treatment under the atmosphere of hydrogen is expensive due to much consumption of gas of hydrogen and runs a risk of explosion, and thus it is costly to make an apparatus of preventing the explosion from taking place.

### SUMMARY OF THE INVENTION

To solve the above problems, it is an object of the present invention to provide a method of heat treating a thin film transistor when forming a poly-silicon thin film transistor using a metal induced lateral crystallization (MILC) method which does not deteriorate performance of the poly-silicon thin film transistor and shortens a MILC heat treatment time under the atmosphere of hydrogen, to thereby reduce a manufacturing process cost and securing a safety.

To accomplish the above object of the present invention, there is provided a method of heat treating a thin film transistor using a metal induced lateral crystallization (MILC) method, the thin film transistor heat treatment method comprising the steps of: forming an amorphous silicon film on an insulation substrate; forming an amorphous silicon thin film transistor using the amorphous silicon film; primarily heat treating the amorphous silicon thin film transistor at a low temperature for a long time under the atmosphere of vacuum, by a MILC method, to thus crystallize the amorphous silicon film in the thin film transistor to be transformed into a poly-crystallized film; and secondarily heat treating the poly-silicon thin film transistor under the atmosphere of hydrogen at a low temperature for a short time, and recovering electrical characteristics of the heat-treated poly-silicon thin film transistor under the vacuum atmosphere.

In the present invention, at the time of heat treating the amorphous silicon thin film transistor for a long time under the atmosphere of vacuum, the amorphous thin film transistor is primarily crystallized by the MILC, so as to be formed into a poly-silicon thin film transistor.

Thereafter, the present invention recovers the bad electrical characteristics of the poly-silicon thin film transistor formed by the vacuum heat treatment through a low-temperature, short-time heat treatment under the atmosphere of hydrogen. As a result, the present invention can avoid a long-time heat treatment of the poly-silicon thin film transistor under the atmosphere of hydrogen.

### BRIEF DESCRIPTION OF THE DRAWINGS

The above and other objects and advantages of the present invention will become more apparent by describing the preferred embodiments thereof in detail with reference to the accompanying drawings in which:

FIGS. 1A through 1D are cross-sectional views for explaining a method of fabricating a crystallized silicon thin film transistor using a conventional MILC method;

FIGS. 2A through 2E are cross-sectional views for explaining a method of fabricating a thin film transistor using a MILC method according to an embodiment of the present invention; and

FIG. 3 is a graphical view showing transfer characteristics of a thin film transistor before and after executing a heat treatment process under the atmosphere of hydrogen for a poly-silicon thin film transistor formed by a vacuum heat treatment process.

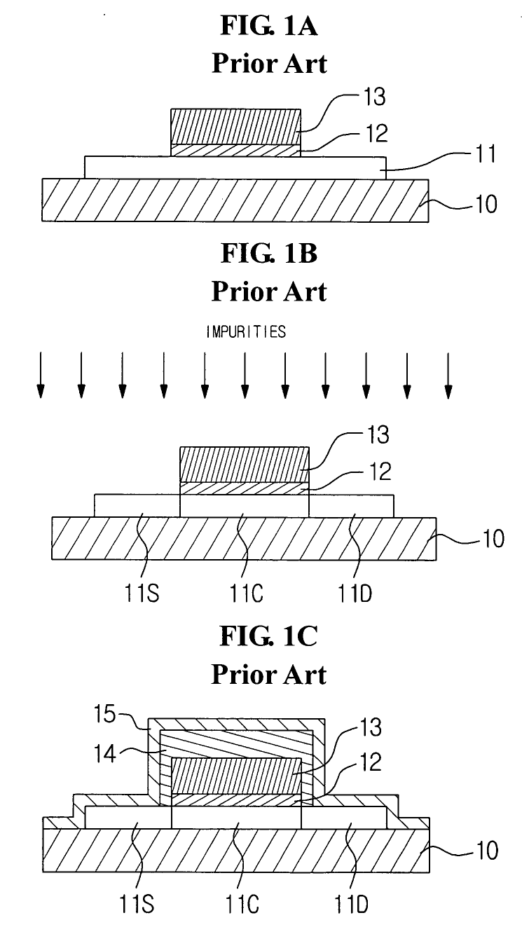

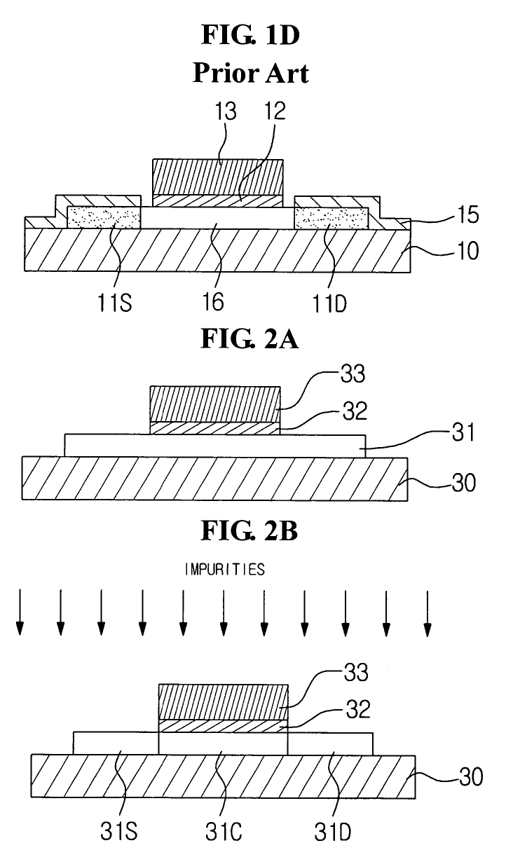

### DETAILED DESCRIPTION OF THE INVENTION

A preferred embodiment of the present invention will be described with reference to the accompanying drawings.

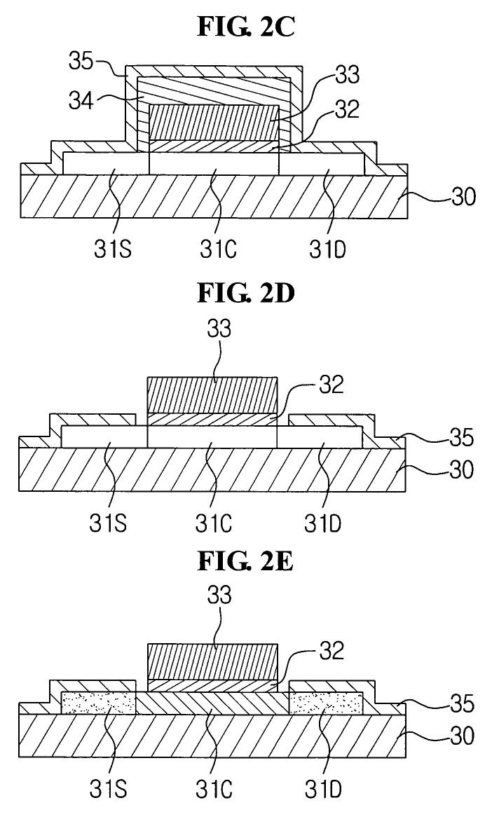

Referring to FIGS. 2A through 2E, a method of fabricating a thin film transistor using a MILC method according to an embodiment of the present invention will be described below.

First, referring to FIG. 2A, a buffer layer 30 made of an oxide film is formed on an insulation substrate such as a glass substrate. Then, an amorphous silicon film is deposited on the insulation substrate, and the amorphous silicon film is patterned using a photographical etching process to form a semiconductor layer 31. An insulation film and a metal film are deposited in sequence and patterned by a photographical etching process, to thereby form a gate electrode 33 and a gate insulation film 32.

Then, as shown in FIG. 2B, a source region 31S and a drain region 31D are formed on the semiconductor layer 31 through an ion injection process. Then, as shown in FIG. 2C, an off-set structure is formed using a photosensitive agent 34 such as photoresist, and a metal film 35 for performing a MILC method is deposited on the entire surface.

That is, the MILC metal film 35 is deposited with a thickness of 1˜10,000 Å, preferably, 10˜200 Å, by any one of sputtering, evaporation by heating, PECVD, and a solution coating. Here, as the applicable material of the metal film 35 is any one selected from the group consisting of Ni, Pd, Ti, Ag, Au, Al, Sn, Sb, Cu, Co, Cr, Mo, Tr, Ru, Rh, Cd, and Pt.

Then, as shown in FIG. 2D, the photosensitive agent 34 is removed from the insulation substrate 30 by a lift-off method.

Referring to FIG. 2E, the insulation substrate on which a thin film transistor including the semiconductor layer 31 made of the amorphous silicon is formed, is primarily heat-treated for a long time in a tubular furnace of vacuum, at a temperature of 400 through 600° C., preferably, at a temperature of 450 through 580° C., for 5˜50 hours, preferably, for 5˜20 hours, to thereby crystallize the amorphous silicon film of the semiconductor layer 31 into an amorphous silicon film so as to be transformed into a poly-silicon film.

As a result, the source and drain regions 31S and 31D contacting the metal film 35 in the semiconductor layer 31 of the amorphous silicon film is crystallized by a MIC (Metal Induced Crystallization) method so as to be transformed into a poly-silicon film. Meanwhile, an amorphous silicon film portion which does not contact the metal film 35, that is, an exposed portion and a channel region 38C located below the gate electrode 32 are crystallized by a MILC method and thus crystallized into a poly-silicon film.

Then, the poly-silicon film is secondarily heat treated at a low temperature for a short time under the atmosphere of hydrogen, that is, at 400˜600° C., preferably, at 450˜580° C., for 0.5˜1 hours, under the hydrogen atmosphere.

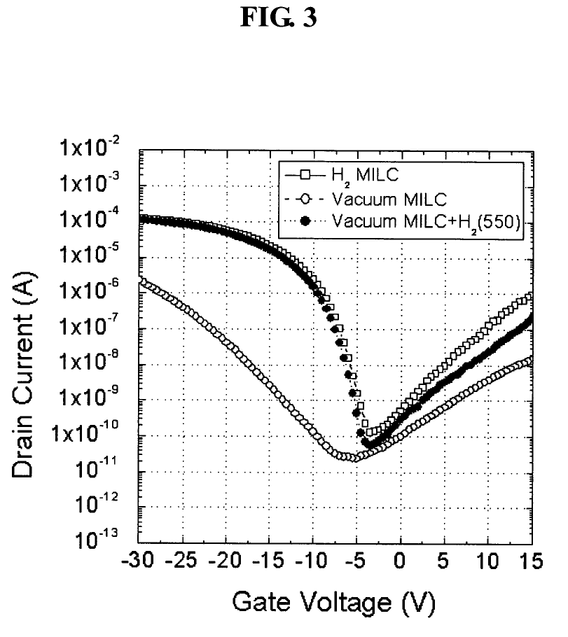

As described above, the long-time vacuum heat treatment and the short-time hydrogen-atmosphere heat treatment are executed in combination. In this case, a voltage-to-current characteristic (denoted as a symbol ●) (Vacuum MILC+H₂(550) of a thin film transistor obtained according to the present invention, a voltage-to-current characteristic (denoted as a symbol □) (H₂ MILC) of a thin film transistor when only a long-time hydrogen-atmosphere heat treatment is executed, and a voltage-to-current characteristic (denoted as a symbol ◯) (Vacuum MILC) of a thin film transistor when only a long-time vacuum-atmosphere heat treatment is executed, are measured and shown in FIG. 3.

As can be seen from the FIG. 3 graph, if the MILC heat treatment is executed under the vacuum atmosphere and then the following heat treatment is executed at 550° C. for thirty minutes, as denoted as symbol ● in the present invention, an on-current (Vg=−30V) which was 2.0×10⁻⁶ A immediately after having performed vacuum heat treatment is increased into 1.1×10⁻⁴ A. This represents a substantially same value as 1.2×10⁻⁴ A which is an on-current value when a MILC heat treatment is executed and denoted as a symbol □ under the hydrogen atmosphere.

Also, a sub-threshold slope which represents a reciprocal of a ratio of a reduced drain current according to a reduced gate voltage near a threshold voltage, is also enhanced into a value similar to that of the case (denoted by the symbol □) that a hydrogen-atmosphere heat treatment is executed, if a hydrogen heat treatment following the vacuum MILC heat treatment is executed as denoted by the symbol ●.

As described above, it can be seen that in the case that the long-time vacuum heat treatment is executed (that is, before a hydrogen heat treatment is executed), electrical characteristics of the poly-silicon thin film transistor are not good, but those are greatly recovered after the short-time hydrogen heat treatment has been executed.

The embodiment according to the present invention has been described with respect to only a thin film transistor having a MILC metal film having an insulation film and an off-set structure. However, the present invention can be applied to a heat treatment process of a MILC thin film transistor (TFT) having a lightly doped drain (LDD) together with the off-set structure.

As described above, a heat treatment method according to the present invention does not perform a long-time heat treatment process under the atmosphere of hydrogen which is expensive and risky when a MILC heat treatment process is executed, but performs a short-time heat treatment process at a low temperature under the atmosphere of hydrogen after having formed a poly-silicon thin film transistor through a vacuum heat treatment process to thereby recover electrical characteristics of the thin film transistor. Thus, the present invention can reduce a processing cost in comparison with the conventional art, and fabricate a poly-silicon thin film transistor by means of a safe method.

As described above, the preferable embodiment of the present invention has been described with reference to the accompanying drawings. However, the present invention is not limited to the above-described embodiment. It is apparent to one who has an ordinary skill in the art that there may be many modifications and variations within the same technical spirit of the invention.

1. A method of heat treating a thin film transistor using a metal induced lateral crystallization (MILC) method, the thin film transistor heat treatment method comprising the steps of:
forming an amorphous silicon film on an insulation substrate; forming an amorphous silicon thin film transistor using the amorphous silicon film;
primarily heat treating the amorphous silicon thin film transistor at a low temperature for a long time under the atmosphere of vacuum, by a MILC method, to thus crystallize the amorphous silicon film in the thin film transistor to be transformed into a poly-crystallized film; and
secondarily heat treating the poly-silicon thin film transistor under the atmosphere of hydrogen at a low temperature for a short time, and recovering electrical characteristics of the heat-treated poly-silicon thin film transistor under the vacuum atmosphere.

2. The MILC thin film transistor heat treating method according to claim 1, wherein the primary heat treatment step is executed at 400˜600° C., preferably 450˜580° C., for 5˜50 hours, preferably 5˜20 hours.

3. The MILC thin film transistor heat treating method according to claim 1, wherein the secondary heat treatment step is executed at 400˜600° C., preferably 450˜580° C., for 0.5˜1 hours.

4. The MILC thin film transistor heat treating method according to claim 1, wherein the MILC metal film is made of any one selected from the group consisting of Ni, Pd, Ti, Ag, Au, Al, Sn, Sb, Cu, Co, Cr, Mo, Tr, Ru, Rh, Cd, and Pt.
